(19) United States
(12) Patent Application Publication
(10) Pub. No.: US 2014/0252298 A1
(43) Pub. Date: Sep. 11, 2014

(54) METHODS AND APPARATUS FOR METAL OXIDE REVERSIBLE RESISTANCE-SWITCHING MEMORY DEVICES

(71) Applicant: SANDISK 3D LLC, Milpitas, CA (US)

(72) Inventors: Yubao Li, San Jose, CA (US); Chu-Chen Fu, San Ramon, CA (US); Timothy James Minvielle, San Jose, CA (US); Huiwen Xu, Sunnyvale, CA (US)

(73) Assignee: SANDISK 3D LLC, Milpitas, CA (US)

(21) Appl. No.: 13/792,100

(22) Filed: Mar. 10, 2013

(51) Int. Cl. H01L 45/00

(52) U.S. Cl. CPC H01L 45/1616; H01L 45/146
USPC 257/4; 438/382

(57) ABSTRACT

In some aspects, a memory cell is provided that includes a first conducting layer, a reversible resistance switching element above the first conducting layer, a second conducting layer above the reversible resistance switching element, and a liner disposed about a sidewall of the reversible resistance switching element. The reversible resistance switching element includes a first metal oxide material, and the liner includes the first metal oxide material. Numerous other aspects are provided.

### BACKGROUND

This invention relates to non-volatile memories, and more particularly to methods and apparatus for metal oxide reversible resistance-switching memory devices.

Non-volatile memories formed from reversible resistivity-switching materials are known. For example, U.S. patent application Ser. No. 11/125,939, filed May 9, 2005 and titled “Rewriteable Memory Cell Comprising A Diode And A Resistance-Switching Material” (hereinafter “the '939 Application”), which is hereby incorporated by reference herein in its entirety for all purposes, describes a rewriteable non-volatile memory cell that includes a diode coupled in series with a reversible resistivity-switching material, such as a metal oxide.

However, fabricating memory devices from rewriteable resistivity-switching materials is difficult, and improved methods of forming memory devices that employ resistivity-switching materials are desirable.

### SUMMARY

In a first aspect of the invention, a memory cell is provided that includes a first conducting layer, a reversible resistance switching element above the first conducting layer, a second conducting layer above the reversible resistance switching element, and a liner disposed about a sidewall of the reversible resistance switching element. The reversible resistance switching element includes a first metal oxide material, and the liner includes the first metal oxide material.

In a second aspect of the invention, a method of forming a memory cell is provided. The method includes forming a first conducting layer, forming a reversible resistance switching element above the first conducting layer, forming a second conducting layer above the reversible resistance switching element, and forming a liner about a sidewall of the reversible resistance switching element. The reversible resistance switching element includes a first metal oxide material, and the liner includes the first metal oxide material.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIGS. 1A-1D are diagrams of previously known fabrication and operation of a previously known metal oxide resistance-switching memory cell;

FIG. 2 is a diagram of an example memory cell in accordance with this invention;

FIG. 3A is a simplified perspective view of an example memory cell in accordance with this invention;

FIG. 3B is a simplified perspective view of a portion of a first example memory level formed from a plurality of the memory cells of FIG. 3A;

FIG. 3C is a simplified perspective view of a portion of a first example three-dimensional memory array in accordance with this invention;

FIG. 3D is a simplified perspective view of a portion of a second example three-dimensional memory array in accordance with this invention;

FIGS. 4A-4C are cross-sectional views of example embodiments of memory cells in accordance with this invention;

FIGS. 5A-5F illustrate cross-sectional views of a portion of a substrate during an example fabrication of a single memory level in accordance with this invention.

### DETAILED DESCRIPTION

A metal-insulator-metal (“MIM”) stack formed from a reversible resistivity-switching material sandwiched between two metal or otherwise conducting layers may serve as a resistance-switching element for a memory cell. The two conducting layers may serve as the top and bottom electrodes of the resistance-switching element, and may be used to apply an electric field across the reversible resistivity-switching material that changes the resistivity of the reversible resistivity-switching material from a high value to a low value and vice versa.

A MIM stack that includes a metal oxide reversible resistivity-switching material may be integrated in series with a diode or transistor to create a metal oxide re-writable memory device, referred to herein as a “MeOx ReRAM.” Manufacturing high-yield MeOx ReRAM memory devices, however, has proven difficult. In particular, it is believed that microscopic physical damage may result to sidewalls of metal oxide material layers during manufacturing of MeOx ReRAM memory devices.

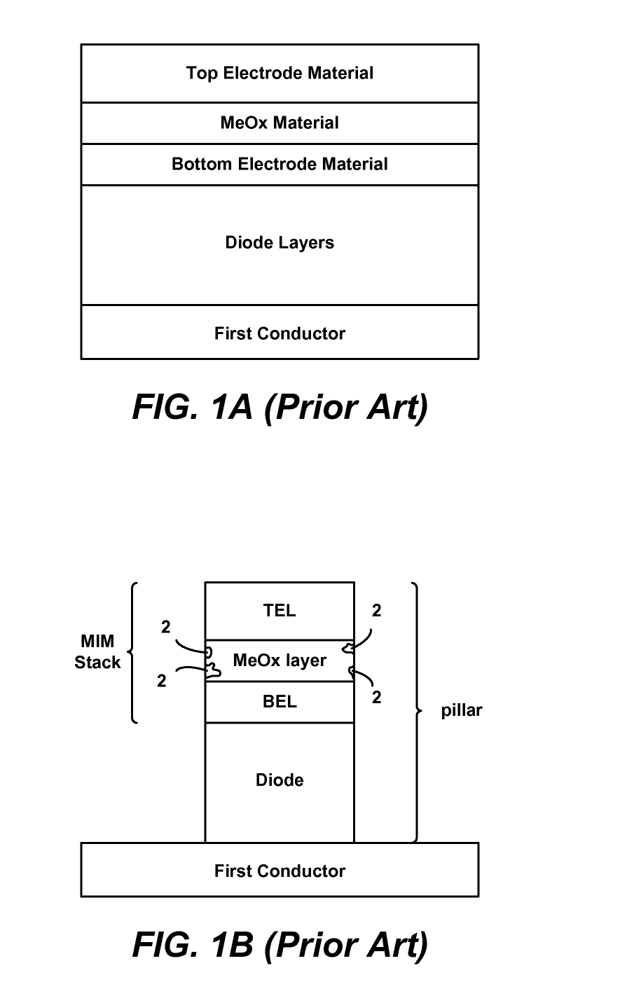

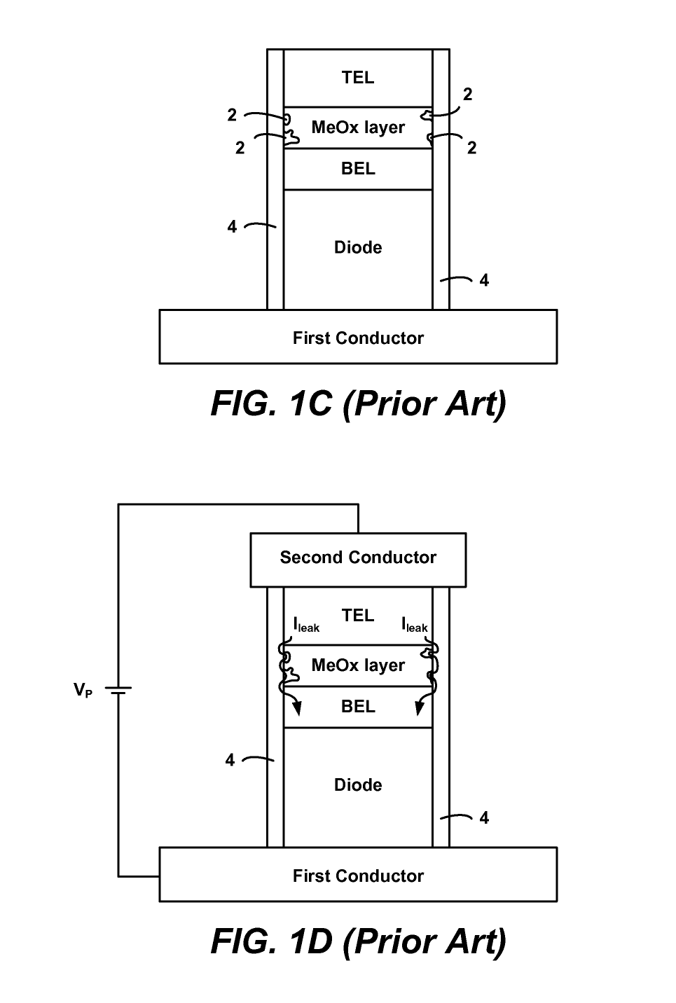

Referring now to FIGS. 1A-1D, a previously known process for fabricating a MeOx ReRAM is described. In a first step, a first conductor material layer, diode material layers, a bottom electrode material layer, a metal oxide material layer, and a top electrode material layer are deposited above a substrate, resulting in the structure shown in FIG. 1A (substrate not shown). The metal oxide material layer may include one or more layers of stoichiometric or non-stoichiometric metal oxide materials.

Next, the top electrode material layer, metal oxide material layer, bottom electrode material layer and diode material layers are patterned and etched to form a pillar that includes a diode in series with a MIM stack, resulting in the structure shown in FIG. 1B. The MIM stack includes a metal oxide switching layer (“MeOx layer”) sandwiched between a top electrode (“TEL”) and a bottom electrode (“BEL”). During etching, microscopic physical damage may result to sidewalls of the MeOx layer, depicted in FIG. 1B as defect regions 2. It is believed that etching-induced defect regions 2 may include dangling bonds or missing atoms. As a result, it is believed that damaged regions 2 may include an oxide material quite different from the metal oxide in the remainder of the MeOx layer.

Next, an insulating liner 4 is formed around the pillar to protect the MeOx layer, resulting in the structure shown in FIG. 1C. The insulating liner 4 typically is fabricated using a different material than that of the MeOx layer. For example, the MeOx layer may be fabricated from a metal oxide, such as hafnium oxide, having a relatively high dielectric constant, whereas insulating liner 4 may be fabricated from a dielectric material, such as silicon dioxide, having a lower dielectric constant. Without wanting to be bound by any particular theory, it is believed that because of structural and compositional differences between insulating liner 4 and the MeOx layer, insulating liner 4 is unable to cure etching-induced defect regions 2.

As a result, it is believed that in the completed MeOx ReRAM, etching-induced defect regions 2 may provide paths for leakage current Iₗₑₐₖ between TEL and BEL, as illustrated in FIG. 1D. Further, because the dielectric constant of insulating liner 4 typically is lower than the dielectric constant of the MeOx layer, insulating liner 4 may be leakier than the MeOx layer. Thus, such previously known MeOx ReRAM devices may exhibit a wide distribution in operating currents and/or biases, and may suffer from a reduced switching yield as a result of mismatch between the material of insulating liner 4 and the MeOx layer.

In accordance with embodiments of the invention, a MeOx ReRAM may be formed that uses the same metal oxide material for the MeOx layer and the liner. Without wanting to be bound by any particular theory, it is believed that by using the same metal oxide material for the liner and the MeOx layer, the liner may “cure” the etching-induced defects in the MeOx layer. In particular, it is believed that the etching-induced defects in the MeOx layer may be substantially eliminated and/or become substantially inactive, and that the MeOx ReRAM devices may operate more uniformly.

These and other embodiments of the invention are described further below with reference to FIGS. 1-5F.

### Example Inventive Memory Cell

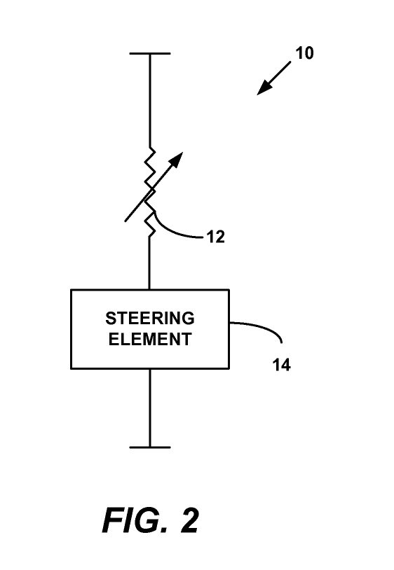

FIG. 2 is a schematic illustration of an example memory cell 10 in accordance with an embodiment of this invention. Memory cell 10 includes a reversible resistance switching element 12 coupled to a steering element 14. Reversible resistance switching element 12 includes a reversible resistivity switching material (not separately shown) having a resistivity that may be reversibly switched between two or more states.

For example, reversible resistance switching element 12 may be in an initial, high-resistance state upon fabrication that is reversibly switchable to a low-resistance state upon application of the appropriate voltage(s) and/or current(s). When used in a memory cell, one resistance state may represent a binary “0,” whereas another resistance state may represent a binary “1,” although more than two data/resistance states may be used. Numerous reversible resistivity switching materials and operation of memory cells employing reversible resistance switching elements are described, for example, in the '939 Application.

Steering element 14 may include a thin film transistor, a diode, a metal-insulator-metal tunneling current device, or another similar steering element that exhibits non-ohmic conduction by selectively limiting the voltage across and/or the current flow through reversible resistance switching element 12. In this manner, memory cell 10 may be used as part of a two or three dimensional memory array and data may be written to and/or read from memory cell 10 without affecting the state of other memory cells in the array.

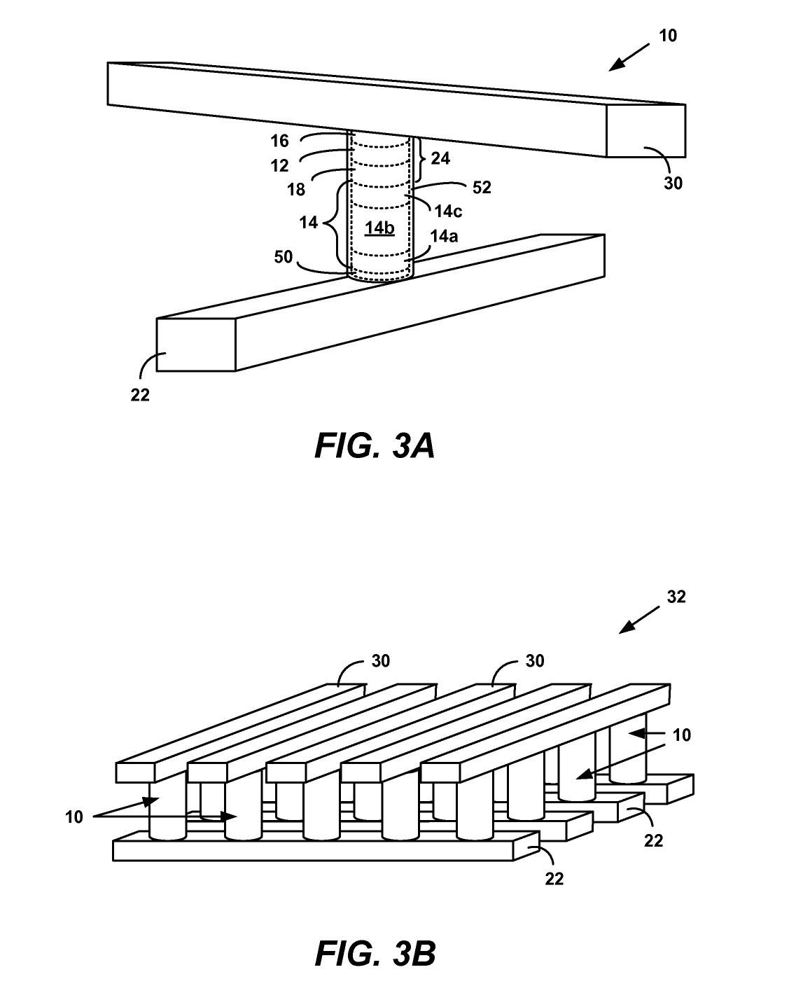

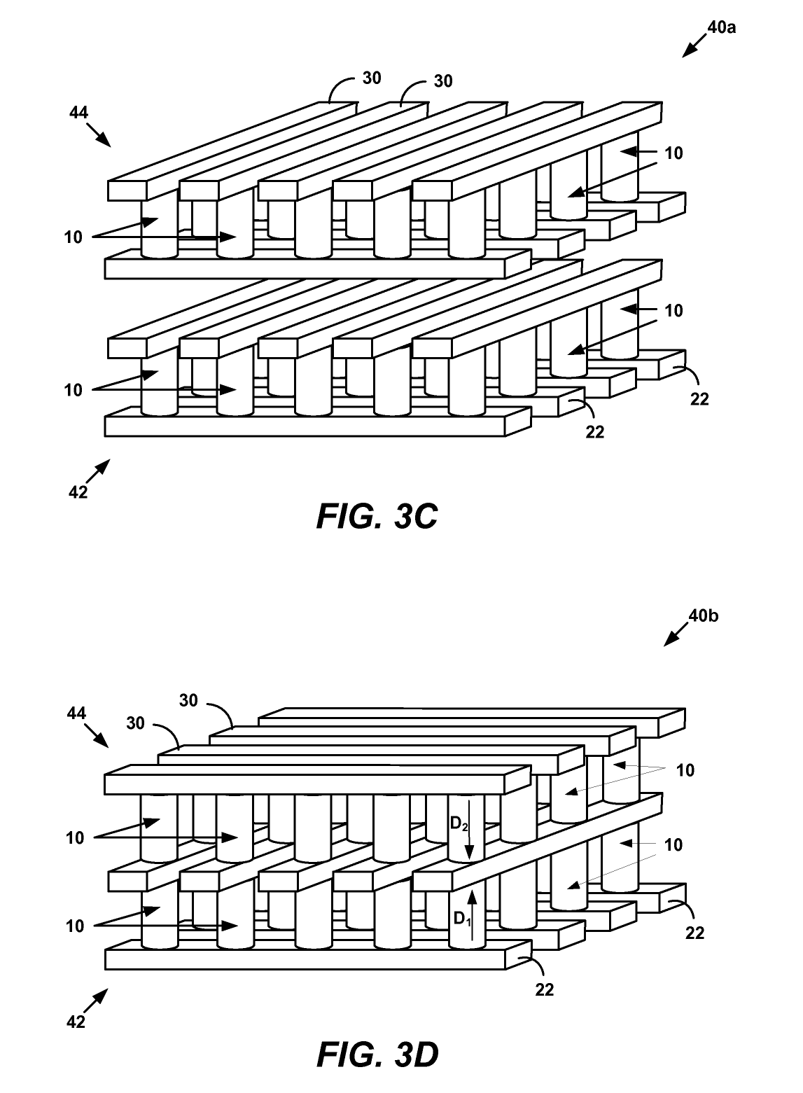

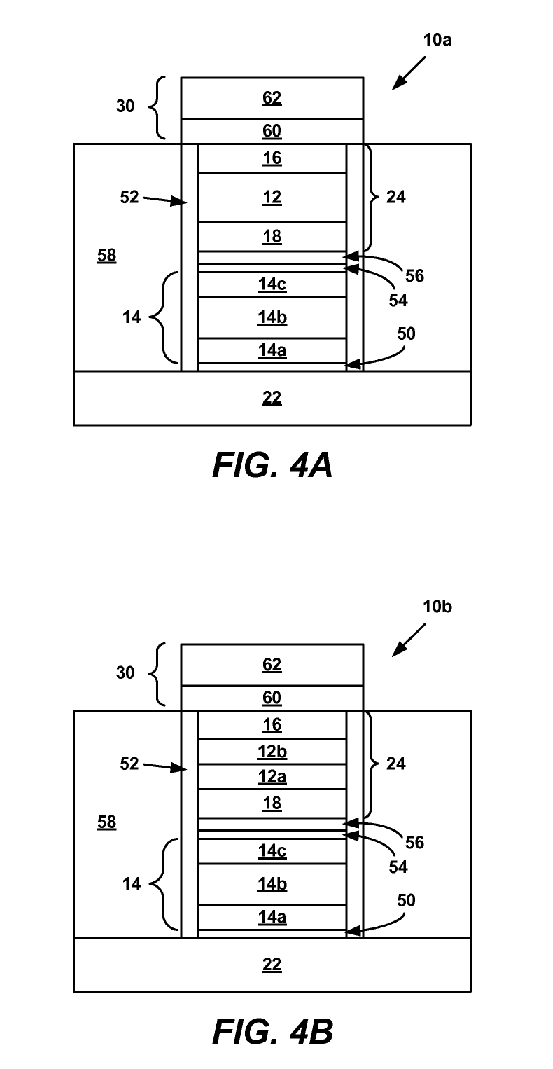

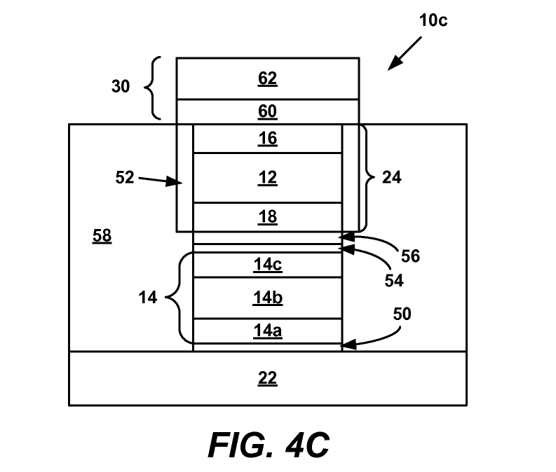

Example embodiments of memory cell 10, reversible resistance switching element 12 and steering element 14 are described below with reference to FIGS. 3A-3D and FIGS. 4A-4B.

### Example Embodiments of Memory Cells and Memory Arrays

FIG. 3A is a simplified perspective view of an example memory cell 10 in accordance with an embodiment of this invention that includes a steering element 14 and a metal oxide reversible resistance switching element 12. Metal oxide reversible resistance switching element 12 is coupled in series with steering element 14 between a first conductor 22 and a second conductor 30.

In some embodiments, a first conducting layer 18 may be formed between metal oxide reversible resistance switching element 12 and steering element 14, a barrier layer 50 may be formed between steering element 14 and first conductor 22, and a second conducting layer 16 may be formed between metal oxide reversible resistance switching element 12 and second conductor 30. First conducting layer 18, barrier layer 50 and second conducting layer 16 each may include titanium, TiN, tantalum, TaN, tungsten, tungsten nitride (“WN”), molybdenum or another similar material.

First conducting layer 18, metal oxide reversible resistance switching element 12, and second conducting layer 16 may form a MIM stack 24 in series with steering element 14, with first conducting layer 18 forming a bottom electrode, and second conducting layer 16 forming a top electrode of MIM stack 24. For simplicity, first conducting layer 18 and second conducting layer 16 will be referred to in the remaining discussion as “bottom electrode 18” and “top electrode 16,” respectively. In some embodiments, metal oxide reversible resistance switching element 12 and/or MIM stack 24 may be positioned below steering element 14.

As discussed above, steering element 14 may include a thin film transistor, a diode, a metal-insulator-metal tunneling current device, or another similar steering element that exhibits non-ohmic conduction by selectively limiting the voltage across and/or the current flow through reversible resistance switching element 12. In the example of FIG. 2A, steering element 14 is a diode. Accordingly, steering element 14 is sometimes referred to herein as “diode 14.”

Diode 14 may include any suitable diode such as a vertical polycrystalline p-n or p-i-n diode, whether upward pointing with an n-region above a p-region of the diode or downward pointing with a p-region above an n-region of the diode. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed. Example embodiments of diode 14 are described below with reference to FIGS. 4A-4B.

Metal oxide reversible resistance switching element 12 may include a metal oxide material (not separately shown) having a resistivity that may be reversibly switched between two or more states. For simplicity, metal oxide reversible resistance switching element 12 will be referred to in the remaining discussion as “MeOx element 12.”

As described in more detail below, memory cells in accordance with this invention, such as example memory cell 10, include a liner 52 that is disposed about a sidewall of MeOx element 12 and is formed from a same metal oxide material as that used to form MeOx element 12. As described in more detail below, in embodiments in which MeOx element 12 is formed using a single stoichiometric metal oxide material (e.g., HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃, or other similar metal oxide), liner 52 is formed from the same stoichiometric metal oxide material as that used to form MeOx element 12.

In embodiments in which MeOx element 12 is formed using a single non-stoichiometric metal oxide material (e.g., Ta₂O₅₋ₓ, ZrO₂₋ₓ, Nb₂O₅₋ₓ, or other similar metal oxide), liner 52 is formed from the corresponding stoichiometric metal oxide material used to form MeOx element 12 (e.g., Ta₂O₅, ZrO₂, Nb₂O₅, etc.). In embodiments in which MeOx element 12 includes a multi-layer stack of more than one metal oxide material, liner 52 is formed from the same metal oxide material as that used to form one of the metal oxide layers in MeOx element 12, and preferably the metal oxide material that exhibits resistivity-switching behavior.

First conductor 22 and/or second conductor 30 may include any suitable conductive material such as tungsten, any appropriate metal, heavily doped semiconductor material, a conductive silicide, a conductive silicide-germanide, a conductive germanide, or the like. In the embodiment of FIG. 3A, first and second conductors 22 and 30, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with the first conductor 22 and/or second conductor 30 to improve device performance and/or aid in device fabrication.

FIG. 3B is a simplified perspective view of a portion of a first memory level 32 formed from a plurality of memory cells 10, such as memory cell 10 of FIG. 3A. For simplicity, MIM stack 24, diode 14, and barrier layer 50 are not separately shown. Memory level 38 is a “cross-point” array including a plurality of bit lines (second conductors 30) and word lines (first conductors 22) to which multiple memory cells are coupled (as shown). Other memory array configurations may be used, as may multiple levels of memory.

For example, FIG. 3C is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 3C for simplicity.

Persons of ordinary skill in the art also will understand that other memory array configurations may be used, as may additional memory levels. In the embodiment of FIG. 3C, all diodes may “point” in the same direction, such as upward or downward depending on whether p-i-n diodes having a p-doped region on the bottom or top of the diodes are employed, simplifying diode fabrication.

In some embodiments, the memory levels may be formed as described in U.S. Pat. No. 6,952,030, titled “High-Density Three-Dimensional Memory Cell” which is hereby incorporated by reference herein in its entirety for all purposes. For instance, the upper conductors of a first memory level may be used as the lower conductors of a second memory level that is positioned above the first memory level as shown in the alternative example three dimensional memory array 40b illustrated in FIG. 3D.

In such embodiments, the diodes on adjacent memory levels preferably point in opposite directions as described in U.S. patent application Ser. No. 11/692,151, filed Mar. 27, 2007, and titled “Large Array Of Upward Pointing P-I-N Diodes Having Large And Uniform Current” (hereinafter “the '151 Application”), which is hereby incorporated by reference herein in its entirety for all purposes.

For example, as shown in FIG. 3D, the diodes of the first memory level 42 may be upward pointing diodes as indicated by arrow D1 (e.g., with p regions at the bottom of the diodes), whereas the diodes of the second memory level 44 may be downward pointing diodes as indicated by arrow D2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

FIG. 4A is a cross-sectional view of an example embodiment of memory cell 10 of FIG. 3A. In particular, FIG. 4A shows an example memory cell 10a which includes MeOx element 12, diode 14, and first and second conductors 22 and 30, respectively. Memory cell 10a also may include bottom electrode 18, barrier layer 50, top electrode 16, a silicide layer 54, and a silicide-forming metal layer 56, as well as adhesion layers, antireflective coating layers and/or the like (not shown) which may be used with first and/or second conductors 22 and 30, respectively, to improve device performance and/or facilitate device fabrication. As described in more detail below, memory cell 10a also includes a liner 52.

Diode 14 may be a vertical p-n or p-i-n diode, which may either point upward or downward. In the embodiment of FIG. 3D in which adjacent memory levels share conductors, adjacent memory levels preferably have diodes that point in opposite directions such as downward-pointing p-i-n diodes for a first memory level and upward-pointing p-i-n diodes for an adjacent, second memory level (or vice versa).

In some embodiments, diode 14 may be formed from a polycrystalline semiconductor material such as polysilicon, a polycrystalline silicon-germanium alloy, polygermanium or any other suitable material. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed.

In some embodiments, a thin germanium and/or silicon-germanium alloy layer (not shown) may be formed on n+ polysilicon region 14a to prevent and/or reduce dopant migration from n+ polysilicon region 14a into intrinsic region 14b. Use of such a layer is described, for example, in U.S. patent application Ser. No. 11/298,331, filed Dec. 9, 2005 and titled “Deposited Semiconductor Structure To Minimize N-Type Dopant Diffusion And Method Of Making” (hereinafter “the '331 Application”), which is hereby incorporated by reference herein in its entirety for all purposes. In some embodiments, a few hundred angstroms or less of silicon-germanium alloy with about 10 at % or more of germanium may be employed.

Barrier layer 50, such as titanium, TiN, tantalum, TaN, tungsten, WN, molybdenum, etc., may be formed between the first conductor 22 and the n+ region 14a (e.g., to prevent and/or reduce migration of metal atoms into the polysilicon regions). In some embodiments, barrier layer 50 may be titanium nitride with a thickness between about 100 to 2000 angstroms, although other materials and/or thicknesses may be used.

If diode 14 is fabricated from deposited silicon (e.g., amorphous or polycrystalline), a silicide layer 54 may be formed on diode 14 to place the deposited silicon in a low resistivity state, as fabricated. Such a low resistivity state allows for easier programming of memory cell 10 as a large voltage is not required to switch the deposited silicon to a low resistivity state.

For example, a silicide-forming metal layer 56 such as titanium or cobalt may be deposited on p+ polysilicon region 14c. During a subsequent anneal step (described below), silicide-forming metal layer 56 and the deposited silicon of diode 14 interact to form silicide layer 54, consuming all or a portion of the silicide-forming metal layer 56. In some embodiments, a nitride layer (not shown) may be formed at a top surface of silicide-forming metal layer 56. For example, if silicide-forming metal layer 56 is titanium, a TiN layer may be formed at a top surface of silicide-forming metal layer 56.

A rapid thermal anneal (“RTA”) step may then be performed to form silicide regions by reaction of silicide-forming metal layer 56 with p+ region 14c. The RTA may be performed at about 540° C. for about 1 minute, and causes silicide-forming metal layer 56 and the deposited silicon of diode 14 to interact to form silicide layer 54, consuming all or a portion of the silicide-forming metal layer 56. An additional, higher temperature anneal (e.g., such as at about 750° C. as described below) may be used to crystallize the diode.

As described in U.S. Pat. No. 7,176,064, titled “Memory Cell Comprising A Semiconductor Junction Diode Crystallized Adjacent To A Silicide,” which is hereby incorporated by reference herein in its entirety for all purposes, silicide-forming materials such as titanium and/or cobalt react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of the diode 14 during annealing). Lower resistivity silicon thereby is provided. Similar results may be achieved for silicon-germanium alloy and/or germanium diodes.

In embodiments in which a nitride layer was formed at a top surface of silicide-forming metal layer 56, following the RTA step, the nitride layer may be stripped using a wet chemistry. For example, if silicide-forming metal layer 56 includes a TiN top layer, a wet chemistry (e.g., ammonium, peroxide, water in a 1:1:1 ratio) may be used to strip any residual TiN. In some embodiments, the nitride layer formed at a top surface of silicide-forming metal layer 56 may remain, or may not be used at all.

Bottom electrode 18 is formed above metal-forming silicide layer 56. Bottom electrode 18, such as titanium, titanium nitride, tantalum, tantalum nitride, tungsten, tungsten nitride, molybdenum, or other similar material, may be formed between diode 14 and MeOx layer 12. In some embodiments, bottom electrode 18 may be titanium nitride with a thickness of between about 10 to 2000 angstroms, more generally between about 20 to 500 angstroms, although other materials and/or thicknesses may be used.

MeOx element 12 is formed above bottom electrode 18. MeOx element 12 may be formed over bottom electrode 18 using any suitable metal oxide formation process, such as atomic layer deposition (“ALD”) or other suitable method. For example, MeOx element 12 may include HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃, or other suitable metal oxide material. Any suitable thickness may be used for MeOx element 12. In one embodiment, MeOx element 12 may have a thickness of about 10 to about 1000, and more preferably about 20-300 angstroms. In some embodiments, MeOx element 12 may be positioned below diode 14.

MeOx element 12 may include a single layer of a single metal oxide material, or may include a stack of multiple layers of metal oxide material. For example, FIG. 4B illustrates an alternative example memory cell 10b that includes a MeOx element 12 having a multi-layer stack of a first metal oxide layer 12a and a second metal oxide layer 12b. Persons of ordinary skill in the art will understand that MeOx element 12 may include multi-layer stacks of more than two metal oxide layers.

First metal oxide layer 12a may be a first metal oxide material, and second metal oxide layer 12b may be a second metal oxide material different from the first metal oxide material. For example, first metal oxide layer 12a and second metal oxide layer 12b may be HfOₓ/AlOₓ, HfOₓ/TiOₓ, or some other combination of metal oxide materials.

Referring again to FIG. 4A, top electrode 16, such as titanium, TiN, tantalum, TaN, tungsten, WN, molybdenum, etc., is formed above MeOx element 12. In some embodiments, top electrode 16 may be TiN with a thickness of about 100 to 2000 angstroms, although other materials and/or thicknesses may be used.

Liner 52 is disposed about a sidewall of MeOx element 12. As shown in FIG. 4A, liner 52 may be disposed about a sidewall of each of top electrode 16, MeOx element 12, bottom electrode 18, silicide-forming metal layer 56, silicide layer 54, diode 14 and barrier layer 50. Alternatively, liner 52 may be disposed about fewer than all of top electrode 16, MeOx element 12, bottom electrode 18, silicide-forming metal layer 56, silicide layer 54, diode 14 and barrier layer 50, as long as liner 52 is disposed at least about a sidewall of MeOx element 12. For example, FIG. 4C illustrates an alternative example memory cell 10C in which liner 52 is disposed only about a sidewall of MIM stack 24.

Referring again to FIG. 4A, liner 52 is formed from the “same” metal oxide material as that used to form MeOx element 12. In particular, in embodiments in which MeOx element 12 is formed using a single stoichiometric metal oxide material (e.g., HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃, or other similar metal oxide), liner 52 is formed from the same stoichiometric metal oxide material as that used to form MeOx element 12.

In embodiments in which MeOx element 12 is formed using a single non-stoichiometric metal oxide material (e.g., Ta₂O₅₋ₓ, ZrO₂₋ₓ, Nb₂O₅₋ₓ, or other similar metal oxide), liner 52 is formed from the corresponding stoichiometric metal oxide material used to form MeOx element 12 (e.g., Ta₂O₅, ZrO₂, Nb₂O₅, etc.).

In embodiments in which MeOx element 12 includes a multi-layer stack of more than one metal oxide material, liner 52 is formed from the same metal oxide material as that used to form one of the metal oxide layers in MeOx element 12. As described in Bandyopadhyay et al. U.S. patent application Ser. No. 13/314,580, filed Dec. 8, 2011, and by Huo et al. U.S. patent application Ser. No. 13/502,832, filed Jun. 30, 2011, each of which is incorporated by reference herein in its entirety for all purposes, it is believed that in metal oxide memory cells that include multi-layer stacks of metal oxide materials, one of the metal oxide layers may function as a resistivity-switching element, whereas the other metal oxide layers may act as in-situ current limiters, tunnel barriers, or some other non-resistivity-switching behavior. In such multi-layer metal oxide memory cells, liner 52 preferably may be formed from the metal oxide material that exhibits resistivity-switching behavior.

Liner 52 may have a thickness between about 3 nm and about 10 nm, more generally between about 1 nm and about 30 nm. Persons of ordinary skill in the art will understand that other thicknesses may be used. Liner 52 may be formed by ALD, or chemical vapor deposition (“CVD”), or other suitable process which can provide conformal deposition of metal oxides.

Without wanting to be bound by any particular theory, it is believed that by using the “same” metal oxide material for liner 52 and MeOx element 12, liner 52 may “cure” some or all etching-induced defects in MeOx element 12. In particular, it is believed that some or all etching-induced defects in MeOx element 12 may be substantially eliminated and/or become substantially inactive, and that memory cells in accordance with thin invention, such as memory cells 10a-10c, may operate more uniformly.

### Example Fabrication Processes for Memory Cells

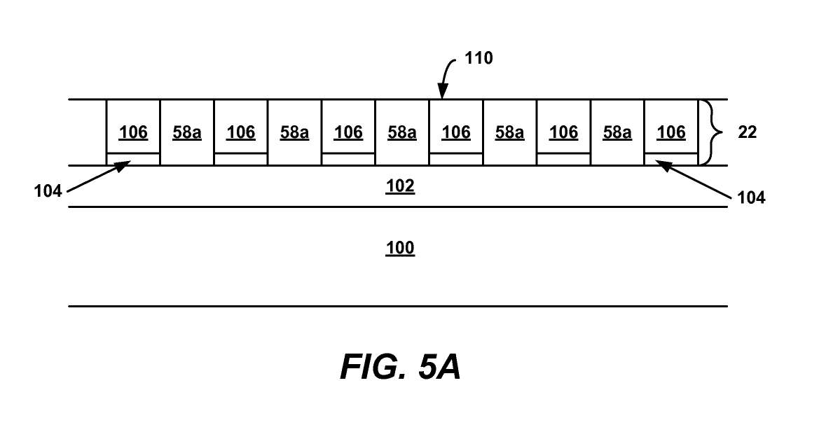

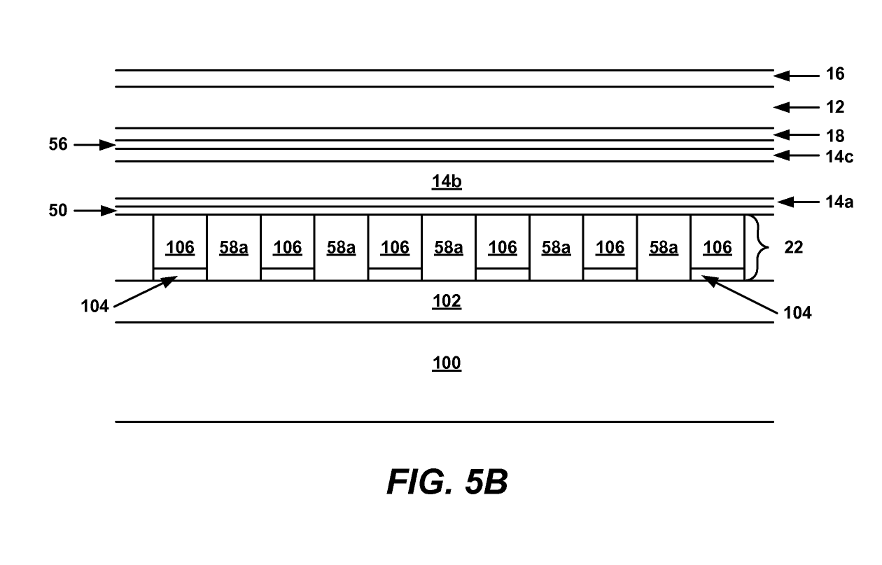

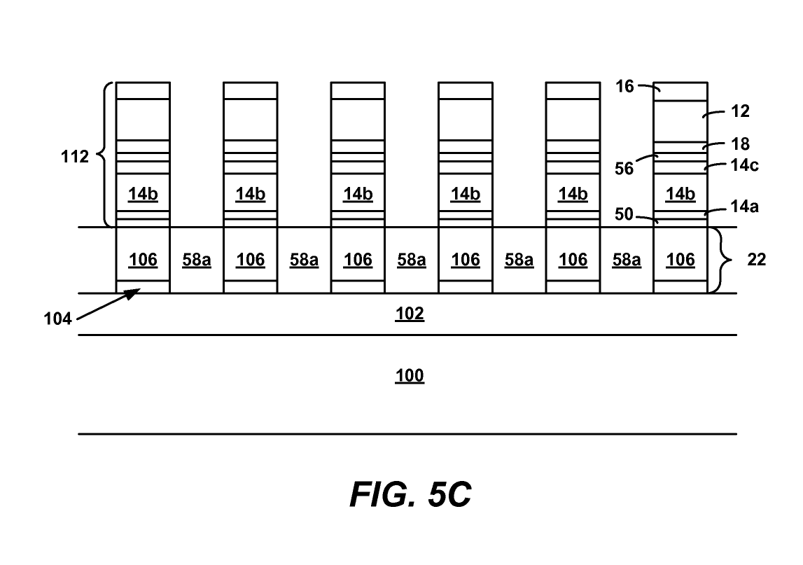

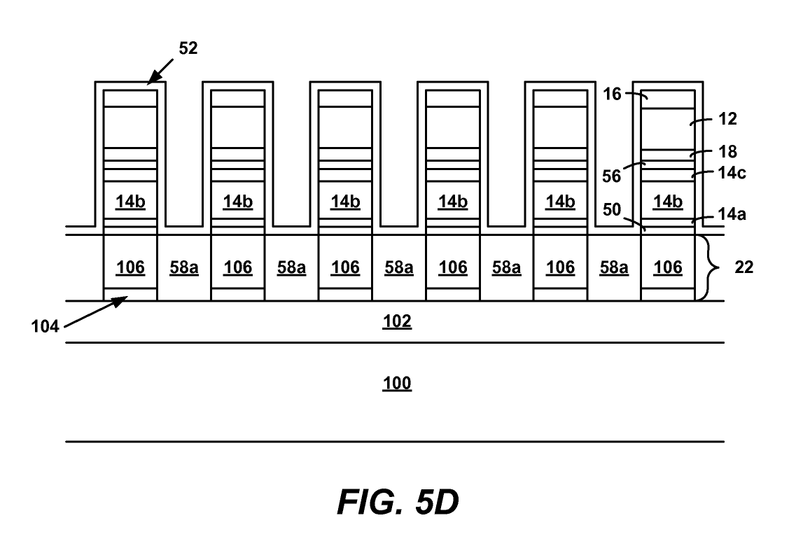

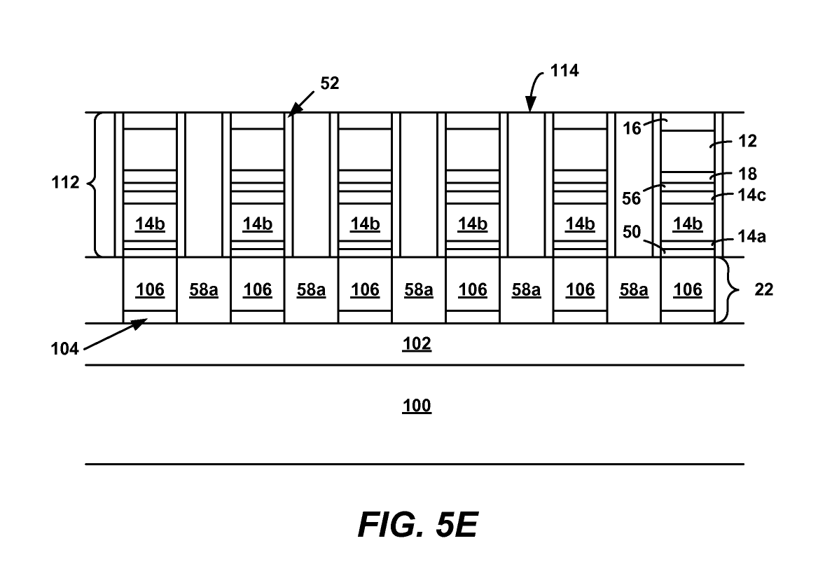

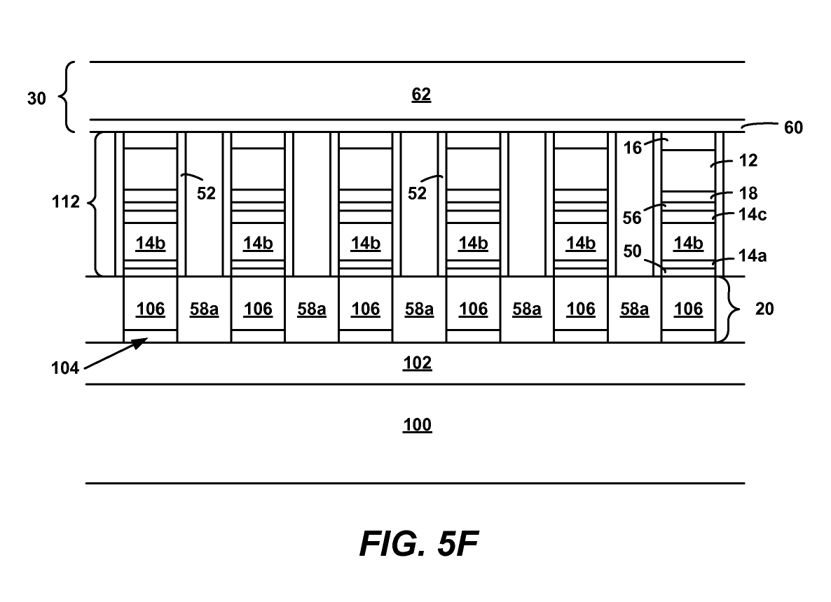

Referring now to FIGS. 5A-5F, a first example method of forming a memory level in accordance with this invention is described. In particular, FIGS. 5A-5F illustrate an example method of forming a memory level including memory cells 10a of FIG. 4A. As will be described below, the first memory level includes a plurality of memory cells that each includes a steering element and a MeOx reversible resistance switching element coupled to the steering element. Additional memory levels may be fabricated above the first memory level (as described previously with reference to FIGS. 3C-3D).

With reference to FIG. 5A, substrate 100 is shown as having already undergone several processing steps. Substrate 100 may be any suitable substrate such as a silicon, germanium, silicon-germanium, undoped, doped, bulk, silicon-on-insulator (“SOI”) or other substrate with or without additional circuitry. For example, substrate 100 may include one or more n-well or p-well regions (not shown).

Isolation layer 102 is formed above substrate 100. In some embodiments, isolation layer 102 may be a layer of silicon dioxide, silicon nitride, silicon oxynitride or any other suitable insulating layer.

Following formation of isolation layer 102, an adhesion layer 104 is formed over isolation layer 102 (e.g., by physical vapor deposition or another method). For example, adhesion layer 104 may be about 20 to about 500 angstroms, and preferably about 100 angstroms, of titanium nitride or another suitable adhesion layer such as tantalum nitride, tungsten nitride, tungsten, molybdenum, combinations of one or more adhesion layers, or the like. Other adhesion layer materials and/or thicknesses may be employed. In some embodiments, adhesion layer 104 may be optional.

After formation of adhesion layer 104, a conductive layer 106 is deposited over adhesion layer 104. Conductive layer 106 may include any suitable conductive material such as tungsten or another appropriate metal, heavily doped semiconductor material, a conductive silicide, a conductive silicide-germanide, a conductive germanide, or the like deposited by any suitable method (e.g., CVD, physical vapor deposition (“PVD,” etc.). In at least one embodiment, conductive layer 106 may comprise about 200 to about 2500 angstroms of tungsten. Other conductive layer materials and/or thicknesses may be used.

Following formation of conductive layer 106, adhesion layer 104 and conductive layer 106 are patterned and etched. For example, adhesion layer 104 and conductive layer 106 may be patterned and etched using conventional lithography techniques, with a soft or hard mask, and wet or dry etch processing. In at least one embodiment, adhesion layer 104 and conductive layer 106 are patterned and etched to form substantially parallel, substantially co-planar first conductors 22. Example widths for first conductors 22 and/or spacings between first conductors 22 range from about 200 to about 2500 angstroms, although other conductor widths and/or spacings may be used.

After first conductors 22 have been formed, a dielectric layer 58a is formed over substrate 100 to fill the voids between first conductors 22. For example, approximately 3000-7000 angstroms of silicon dioxide may be deposited on the substrate 100 and planarized using chemical mechanical polishing or an etchback process to form a planar surface 110. Planar surface 110 includes exposed top surfaces of first conductors 22 separated by dielectric material (as shown). Other dielectric materials such as silicon nitride, silicon oxynitride, low K dielectrics, etc., and/or other dielectric layer thicknesses may be used. Example low K dielectrics include carbon doped oxides, silicon carbon layers, or the like.

In other embodiments of the invention, first conductors 22 may be formed using a damascene process in which dielectric layer 58a is formed, patterned and etched to create openings or voids for first conductors 22. The openings or voids then may be filled with adhesion layer 104 and conductive layer 106 (and/or a conductive seed, conductive fill and/or barrier layer if needed). Adhesion layer 104 and conductive layer 106 then may be planarized to form planar surface 110. In such an embodiment, adhesion layer 104 will line the bottom and sidewalls of each opening or void.

Following planarization, the diode structures of each memory cell are formed. With reference to FIG. 5B, a barrier layer 50 is formed over planarized top surface 110 of substrate 100. In some embodiments, barrier layer 50 may be about 20 to about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 50, deposition of the semiconductor material used to form the diode of each memory cell begins (e.g., diode 14 in FIGS. 2 and 4A). Each diode may be a vertical p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, downward-pointing diode is described herein. It will be understood that other materials and/or diode configurations may be used.

With reference to FIG. 5B, following formation of barrier layer 50, a heavily doped n+ silicon layer 14a is deposited on barrier layer 50. In some embodiments, n+ silicon layer 14a is in an amorphous state as deposited. In other embodiments, n+ silicon layer 14a is in a polycrystalline state as deposited. CVD or another suitable process may be employed to deposit n+ silicon layer 14a. In at least one embodiment, n+ silicon layer 14a may be formed, for example, from about 100 to about 1000 angstroms, preferably about 100 angstroms, of phosphorus or arsenic doped silicon having a doping concentration of about 10²¹ cm⁻³. Other layer thicknesses, doping types and/or doping concentrations may be used. N+ silicon layer 14a may be doped in situ, for example, by flowing a donor gas during deposition. Other doping methods may be used (e.g., implantation).

After deposition of n+ silicon layer 14a, a lightly doped, intrinsic and/or unintentionally doped silicon layer 14b may be formed over n+ silicon layer 14a. In some embodiments, intrinsic silicon layer 14b may be in an amorphous state as deposited. In other embodiments, intrinsic silicon layer 14b may be in a polycrystalline state as deposited. CVD or another suitable deposition method may be employed to deposit intrinsic silicon layer 14b. In at least one embodiment, intrinsic silicon layer 14b may be about 300 to about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on n+ silicon layer 14a prior to depositing intrinsic silicon layer 14b to prevent and/or reduce dopant migration from n+ silicon layer 14a into intrinsic silicon layer 14b (as described in the '331 Application).

P-type silicon may be either deposited and doped by ion implantation or may be doped in situ during deposition to form a p+ silicon layer 14c. For example, a blanket p+ implant may be employed to implant boron a predetermined depth within intrinsic silicon layer 14b. Example implantable molecular ions include BF₂, BF₃, B and the like. In some embodiments, an implant dose of about 1-5×10¹⁵ ions/cm² may be employed. Other implant species and/or doses may be used. Further, in some embodiments, a diffusion process may be employed. In at least one embodiment, the resultant p+ silicon layer 14c has a thickness of about 100-700 angstroms, although other p+ silicon layer sizes may be used.

Following formation of p+ silicon layer 14c, a silicide-forming metal layer 56 is deposited over p+ silicon layer 14c. Example silicide-forming metals include sputter or otherwise deposited titanium or cobalt. In some embodiments, silicide-forming metal layer 56 has a thickness of about 10 to about 200 angstroms, preferably about 20 to about 50 angstroms and more preferably about 20 angstroms. Other silicide-forming metal layer materials and/or thicknesses may be used. A nitride layer (not shown) may be formed at the top of silicide-forming metal layer 56.

Following formation of silicide-forming metal layer 56, an RTA step may be performed at about 540° C. for about one minute to form silicide layer 54 (FIG. 3A), consuming all or a portion of the silicide-forming metal layer 56. Following the RTA step, any residual nitride layer from silicide-forming metal layer 56 may be stripped using a wet chemistry, as described above. Other annealing conditions may be used.

Following the RTA step and the nitride strip step, bottom electrode 18 is formed above silicide layer 54. Bottom electrode 18 may be titanium, titanium nitride, tantalum, tantalum nitride, tungsten, tungsten nitride, molybdenum, or other similar material. In some embodiments, bottom electrode 18 may be titanium nitride with a thickness of between about 10 to 2000 angstroms, more generally between about 20 to 500 angstroms, although other materials and/or thicknesses may be used. Any suitable method may be used to form bottom electrode 18. For example, CVD, PVD, ALD, plasma enhanced ALD (“PEALD”), or the like may be employed.

MeOx element 12 is formed above bottom electrode 18. MeOx element 12 may be formed over bottom electrode 18 using any suitable metal oxide formation process, such as ALD or other suitable method. For example, MeOx element 12 may include HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃, or other suitable metal oxide material.

Any suitable thickness may be used for MeOx element 12. In one embodiment, MeOx element 12 may have a thickness of about 10 to about 1000, and more preferably about 20-300 angstroms. In some embodiments, MeOx element 12 may be positioned below diode 14. As described above, MeOx element 12 may include a single layer of a single metal oxide material, or may include a stack of multiple layers of metal oxide material.

Above MeOx element 12, top electrode 16 is formed. Top electrode 16 may be about 20 to about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed. For example, in some embodiments, the top electrode 16 may be TiN with a thickness of about 100 to 2000 angstroms.

In at least one embodiment, top electrode 16 may be deposited without a pre-clean or pre-sputter step prior to deposition. Example deposition process conditions are as set forth in Table 1.

TABLE 1
EXAMPLE ADHESION/BARRIER LAYER
DEPOSITION PARAMETERS

| | EXAMPLE | PREFERRED |
|---|---|---|
| PROCESS PARAMETER | RANGE | RANGE |
| Argon Flow Rate (sccm) | 20-40 | 20-30 |
| Ar With Dilute H₂ | 0-30 | 0-10 |
| (<10%) Flow Rate (sccm) | | |
| Nitrogen Flow Rate | 50-90 | 60-70 |
| (sccm) | | |
| Pressure (milliTorr) | 1-5000 | 1800-2400 |
| Power (Watts) | 10-9000 | 2000-9000 |
| Power Ramp Rate | 10-5000 | 2000-4000 |
| (Watts/sec) | | |
| Process Temperature (° C.) | 100-600 | 200-350 |
| Deposition Time (sec) | 5-200 | 10-150 |

Other flow rates, pressures, powers, power ramp rates, process temperatures and/or deposition times may be used.

Example deposition chambers include the Endura 2 tool available from Applied Materials, Inc. of Santa Clara, Calif. Other processing tools may be used. In some embodiments, a buffer chamber pressure of about 1-2×10⁻⁷ Torr and a transfer chamber pressure of about 2-5×10⁻⁸ Torr may be used. The deposition chamber may be stabilized for about 250-350 seconds with about 60-80 sccm Ar, 60-70 sccm N₂, and about 5-10 sccm of Ar with dilute H₂ at about 1800-2400 milliTorr. In some embodiments, it may take about 2-5 seconds to strike the target. Other buffer chamber pressures, transfer chamber pressures and/or deposition chamber stabilization parameters may be used.

As shown in FIG. 5C, top electrode 16, MeOx element 12, bottom electrode 18, silicide-forming metal layer 56, diode layers 14a-14c, and barrier layer 50 are patterned and etched to form pillars 112. Pillars 112 may be formed above corresponding conductors 22 and have substantially the same width as conductors 22, for example, although other widths may be used. Some misalignment may be tolerated. The memory cell layers may be patterned and etched in a single pattern/etch procedure or using separate pattern/etch steps. In at least one embodiment, top electrode 16, MeOx element 12, and bottom electrode 18 are etched together to form MIM stack 24 (FIG. 4A).

For example, photoresist may be deposited, patterned using standard photolithography techniques, layers 50, 14a-14c, 56, 18, 12 and 16 may be etched, and then the photoresist may be removed. Alternatively, a hard mask of some other material, for example silicon dioxide, may be formed on top of top electrode 16, with bottom antireflective coating (“BARC”) on top, then patterned and etched. Similarly, dielectric antireflective coating (“DARC”) may be used as a hard mask. In some embodiments, one or more additional metal layers may be formed above the MeOx element 12 and diode 14 and used as a metal hard mask that remains part of the pillars 112. Use of metal hard masks is described, for example, in U.S. patent application Ser. No. 11/444,936, filed May 13, 2006 and titled “Conductive Hard Mask To Protect Patterned Features During Trench Etch” (hereinafter “the '936 Application”) which is hereby incorporated by reference herein in its entirety for all purposes.

Pillars 112 may be formed using any suitable masking and etching process. For example, layers 50, 14a-14c, 56, 18, 12, and 16 may be patterned with about 1 to about 1.5 micron, more preferably about 1.2 to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

Liner 52 is deposited conformally over pillars 112, as illustrated in FIG. 5D. Liner 52 is formed from the “same” metal oxide material as that used to form MeOx element 12. In particular, in embodiments in which MeOx element 12 is formed using a single stoichiometric metal oxide material (e.g., HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃, or other similar metal oxide), liner 52 is formed from the same stoichiometric metal oxide material as that used to form MeOx element 12.

In embodiments in which MeOx element 12 is formed using a single non-stoichiometric metal oxide material (e.g., Ta₂O₅₋ₓ, ZrO₂₋ₓ, Nb₂O₅₋ₓ, or other similar metal oxide), liner 52 is formed from the corresponding stoichiometric metal oxide material used to form MeOx element 12 (e.g., Ta₂O₅, ZrO₂, Nb₂O₅, etc.).

In embodiments in which MeOx element 12 includes a multi-layer stack of more than one metal oxide material, liner 52 is formed from the same metal oxide material as that used to form one of the metal oxide layers in MeOx element 12. In such multi-layer metal oxide memory cells, liner 52 preferably may be formed from the metal oxide material that exhibits resistivity-switching behavior.

Liner 52 may have a thickness between about 3 nm and about 10 nm, more generally between about 1 nm and about 30 nm. Persons of ordinary skill in the art will understand that other thicknesses may be used. Liner 52 may be formed by ALD, or CVD, or other suitable process.

A dielectric layer 58b is deposited over pillars 112 to fill the voids between pillars 112. For example, approximately 2000-7000 angstroms of silicon dioxide may be deposited and planarized using chemical mechanical polishing or an etchback process to form a planar surface 114, resulting in the structure illustrated in FIG. 5E. Planar surface 114 includes exposed top surfaces of pillars 112 separated by dielectric material 58b (as shown). Other dielectric materials such as silicon nitride, silicon oxynitride, low K dielectrics, etc., and/or other dielectric layer thicknesses may be used.

With reference to FIG. 5F, second conductors 30 may be formed above pillars 112 in a manner similar to the formation of first conductors 22. For example, in some embodiments, one or more barrier layers and/or adhesion layers 60 may be deposited over pillars 112 prior to deposition of a conductive layer 62 used to form second conductors 30.

Conductive layer 62 may be formed from any suitable conductive material such as tungsten, another suitable metal, heavily doped semiconductor material, a conductive silicide, a conductive silicide-germanide, a conductive germanide, or the like deposited by PVD or any other any suitable method (e.g., CVD, etc.). Other conductive layer materials may be used. Barrier layer and/or adhesion layer 60 may include titanium nitride or another suitable layer such as tantalum nitride, tungsten nitride, tungsten, molybdenum, combinations of one or more layers, or any other suitable material(s). The deposited conductive layer 62 and barrier and/or adhesion layer 60 may be patterned and etched to form second conductors 30. In at least one embodiment, second conductors 30 are substantially parallel, substantially coplanar conductors that extend in a different direction than first conductors 22.

In other embodiments of the invention, second conductors 30 may be formed using a damascene process in which a dielectric layer is formed, patterned and etched to create openings or voids for conductors 30. The openings or voids may be filled with adhesion layer 60 and conductive layer 62 (and/or a conductive seed, conductive fill and/or barrier layer if needed). Adhesion layer 60 and conductive layer 62 then may be planarized to form a planar surface.

Following formation of second conductors 30, the resultant structure may be annealed to crystallize the deposited semiconductor material of diodes 14 (and/or to form silicide regions by reaction of the silicide-forming metal layer 56 with p+ region 14c). The lattice spacing of titanium silicide and cobalt silicide are close to that of silicon, and it appears that such silicide layers may serve as “crystallization templates” or “seeds” for adjacent deposited silicon as the deposited silicon crystallizes. Lower resistivity diode material thereby is provided. Similar results may be achieved for silicon-germanium alloy and/or germanium diodes.

Thus in at least one embodiment, a crystallization anneal may be performed for about 10 seconds to about 2 minutes in nitrogen at a temperature of about 600 to 800° C., and more preferably between about 650 and 750° C. Other annealing times, temperatures and/or environments may be used.

Additional memory levels may be similarly formed above the memory level of FIGS. 5A-5F. Persons of ordinary skill in the art will understand that alternative memory cells in accordance with this invention may be fabricated with other suitable techniques.

The foregoing description discloses only example embodiments of the invention. Modifications of the above disclosed apparatus and methods which fall within the scope of the invention will be readily apparent to those of ordinary skill in the art. For instance, in any of the above embodiments, the MeOx material may be located below diode(s) 14.

Accordingly, although the present invention has been disclosed in connection with example embodiments thereof, it should be understood that other embodiments may fall within the spirit and scope of the invention, as defined by the following claims.

1. A memory cell comprising:
a first conducting layer;
a reversible resistance switching element above the first conducting layer;
a second conducting layer above the reversible resistance switching element; and
a liner disposed about a sidewall of the reversible resistance switching element,
wherein:
the reversible resistance switching element comprises a first metal oxide material, and
the liner comprises the first metal oxide material.

2. The memory cell of claim 1, wherein the first metal oxide material comprises one or more of HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, Co₂O₃, WO₃, TiO₂, SrZrO₃, SrTiO₃.

3. The memory cell of claim 1, wherein first metal oxide material comprises a stoichiometric metal oxide material, and the liner comprises the stoichiometric metal oxide material.

4. The memory cell of claim 1, wherein first metal oxide material comprises a non-stoichiometric metal oxide material, and the liner comprises a corresponding stoichiometric metal oxide material.

5. The memory cell of claim 1, wherein the reversible resistance-switching element comprises a stack of the first metal oxide material and a second metal oxide material.

6. The memory cell of claim 5, wherein the first metal oxide material exhibits resistivity-switching behavior.

7. The memory cell of claim 1, wherein the liner comprises a thickness between about 1 nm and about 30 nm.

8. The memory cell of claim 1, wherein the liner is formed by any of atomic layer deposition, or chemical vapor deposition.

9. The memory cell of claim 1, further comprising a steering element coupled in series with the reversible resistance-switching element.

10. The memory cell of claim 1, further comprising a diode coupled in series with the reversible resistance-switching element.

11. A method of forming a memory cell, the method comprising:
forming a first conducting layer;
forming a reversible resistance switching element above the first conducting layer;
forming a second conducting layer above the reversible resistance switching element; and
forming a liner about a sidewall of the reversible resistance switching element,
wherein:
the reversible resistance switching element comprises a first metal oxide material, and
the liner comprises the first metal oxide material.

12. The method cell of claim 11, wherein the first metal oxide material comprises one or more of HfO₂, Al₂O₃, HfSiOₓ, HfSiOₓN_{y}, HfAlOₓ, Nb₂O₅, Ta₂O₅, ZrO₂, Cr₂O₃, Fe₂O₃, Ni₂O₃, CO₂O₃, WO₃, TiO₂, SrZrO₃, SrTiO₃.

13. The method cell of claim 11, wherein first metal oxide material comprises a stoichiometric metal oxide material, and the liner comprises the stoichiometric metal oxide material.

14. The method cell of claim 11, wherein first metal oxide material comprises a non-stoichiometric metal oxide material, and the liner comprises a corresponding stoichiometric metal oxide material.

15. The method cell of claim 11, wherein the reversible resistance-switching element comprises a stack of the first metal oxide material and a second metal oxide material.

16. The method of claim 15, wherein the first metal oxide material exhibits resistivity-switching behavior.

17. The method cell of claim 11, wherein the liner comprises a thickness between about 1 nm and about 30 nm.

18. The method cell of claim 11, wherein the liner is formed by any of atomic layer deposition, or chemical vapor deposition.

19. The method cell of claim 11, further comprising forming a steering element coupled in series with the reversible resistance-switching element.

20. The method cell of claim 11, further comprising forming a diode coupled in series with the reversible resistance-switching element.
